(19) United States
(12) Patent Application Publication
(10) Pub. No.: US 2009/0128213 A1
(43) Pub. Date: May 21, 2009

(54) INTEGRATED CIRCUIT CLOCK STRUCTURE

(75) Inventors: Ahmadreza (Reza) Rofougaran, Newport Coast, CA (US); Maryam Rofougaran, Rancho Palos Verdes, CA (US); Hooman Darabi, Irvine, CA (US)

Correspondence Address: GARLICK HARRISON & MARKISON, P.O. BOX 160727, AUSTIN, TX, 78716-0727, US

(73) Assignee: BROADCOM CORPORATION, Irvine, CA (US)

(21) Appl. No.: 11/942,297

(22) Filed: Nov. 19, 2007

(51) Int. Cl. H03K 3/00

(52) U.S. Cl. 327/295

(57) ABSTRACT

An integrated circuit includes first and second circuits, and a clock structure. The clock structure consists of a crystal oscillation circuit, a plurality of buffers, and a plurality of clock generating modules. An input of each of the plurality of buffers is coupled to receive a reference clock signal from the crystal oscillation circuit. Each of the plurality of clock generating modules is coupled to a corresponding one of the plurality of buffers and, when enabled, generates a clock signal.

### CROSS REFERENCE TO RELATED PATENTS

NOT APPLICABLE

### STATEMENT REGARDING FEDERALLY SPONSORED RESEARCH OR DEVELOPMENT

NOT APPLICABLE

### INCORPORATION-BY-REFERENCE OF MATERIAL SUBMITTED ON A COMPACT DISC

NOT APPLICABLE

### BACKGROUND OF THE INVENTION

1. Technical Field of the Invention

This invention relates generally to integrated circuits and more particularly to clock structures of an integrated circuit.

2. Description of Related Art

Integrated circuits (ICs) are known to include a plurality of different circuits on one or more die in a single IC package. Many of the different circuits require a clock signal to function. For example, processors, memory, many analog to digital converters, many digital to analog converters, state machines, most logic circuits, etc. require at least one clock signal to function. To provide the clock signals for the different circuits, an IC typically includes multiple clock circuits.

With multiple clock circuits, noise associated with clock circuits may adversely affect noise sensitive circuits clocked by a different clock circuit. In addition, if multiple clock circuits require their own crystal oscillator, which are relatively expensive parts, the cost of a device incorporating the IC increases. One solution to overcome these problems is to use a single crystal and a single crystal oscillation circuit to generate a reference oscillation. The reference oscillation is serially buffered to provide taps for circuit specific clock generators. While this reduces the number crystals needed to one, it presents a few new issues. For instance, with the serially connected buffers, there is a dependency between the difference clock generators such that noise may be coupled via the serial connection. Further, separate power supplies cannot be used for the different clock generators. Still further, a clock generator, if not needed, cannot be gated off. Even further, buffers first in the serial connection need to be sized to power its associated clock generator and all others down the line, which increases its power consumption.

Therefore, a need exists for a clock structure that utilizes a single clock reference to generate a plurality of clock signals while overcoming at least one of the above mentioned issues with a single crystal, a single crystal oscillation circuit, and serially buffering the reference oscillation.

### BRIEF SUMMARY OF THE INVENTION

The present invention is directed to apparatus and methods of operation that are further described in the following Brief Description of the Drawings, the Detailed Description of the Invention, and the claims. Other features and advantages of the present invention will become apparent from the following detailed description of the invention made with reference to the accompanying drawings.

### BRIEF DESCRIPTION OF THE SEVERAL VIEWS OF THE DRAWING(S)

FIG. 1 is a schematic block diagram of an embodiment of an integrated circuit in accordance with the present invention;

FIG. 2 is a schematic block diagram of another embodiment of an integrated circuit in accordance with the present invention;

FIG. 3 is a schematic block diagram of another embodiment of an integrated circuit in accordance with the present invention;

FIG. 4 is a schematic block diagram of another embodiment of an integrated circuit in accordance with the present invention;

FIG. 5 is a schematic block diagram of another embodiment of an integrated circuit in accordance with the present invention;

FIG. 6 is a schematic block diagram of another embodiment of an integrated circuit in accordance with the present invention; and

FIG. 7 is a schematic block diagram of an embodiment of a clock structure in accordance with the present invention.

### DETAILED DESCRIPTION OF THE INVENTION

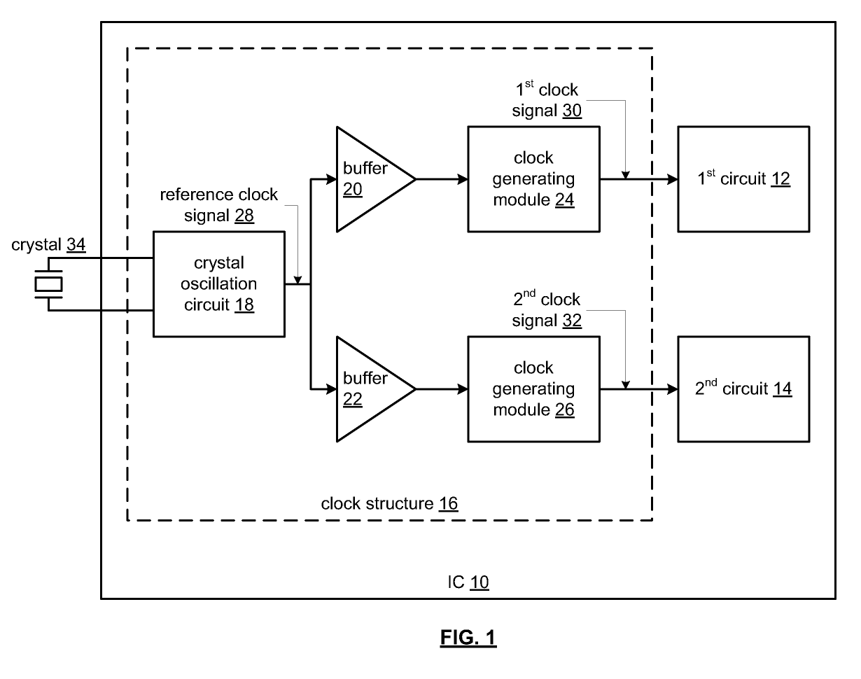

FIG. 1 is a schematic block diagram of an embodiment of an integrated circuit 10 that includes a first circuit 12, a second circuit 14, and a clock structure 16. The clock structure 16 is coupled to an off-chip crystal 34 and includes a crystal oscillation circuit 18, a plurality of buffers 20-22, and a plurality of clock generating modules 24-26. The crystal oscillation circuit 18, which may include an inverter, converts a vibration of the crystal 34 into a reference clock signal 28. For example, the crystal 34 may produce a vibration at 26 MHz, which is converted into a 26 MHz clock signal. In an alternative embodiment, the crystal 24 and crystal oscillation circuit 18 are off-chip and the IC 10 receives the reference clock signal 28 via an input/output (I/O) pin, or pins.

Buffers 20-22 individually buffer the reference clock signal 18 and provide the buffered reference clock signal 18 to their corresponding clock generating module 24-26. For example, buffer 20 buffers the reference clock signal 18 and provides the buffered clock signal to clock generating module 24 and buffer 22 buffers the reference clock signal 18 and provides the buffered clock signal to clock generating module 26.

The first clock generating module 24, when enabled, generates a first clock signal 30 based on the buffered reference clock signal 28 received from buffer 20. Similarly, the second clock generating module 26, when enabled, generates a second clock signal 32 based on the buffered reference clock signal 28 received from buffer 22. The first and/or second clock generating module 24 and/or 26 may include one or more of a phase locked loop (PLL), a fractional-N synthesizer, a counter logic circuit, a frequency multiplier, and a frequency divider to generate one or more fixed or adjustable clock signals. For example, the first clock generating module 24 may be a PLL that converts the buffered reference clock signal 28 into a fixed 2.4 GHz clock signal and the second clock generating module 26 may be a fractional N synthesizer that converts the buffered reference clock signal 28 in 2.40-2.48 GHz clock signal based on a fractional setting of the fractional N synthesizer.

Each of the first and second circuits 12 and 14 may be a microprocessor, micro-controller, digital signal processor, microcomputer, central processing unit, field programmable gate array, programmable logic device, state machine, logic circuitry, analog circuitry, digital circuitry, and/or any device that manipulates signals (analog and/or digital) based on hard coding of the circuitry and/or operational instructions. In this embodiment, the first circuit 12 receives the one or more first clock signals 30 from the first clock generating module 24 to perform a first function at a rate corresponding to a first clock signal 30. Similarly, the second circuit 14 receives the one or more second clock signals 32 from the second clock generating module 26 to perform a second function at a rate corresponding to a second clock signal 32. With such an embodiment, a clock structure that utilizes a single clock reference to generate a plurality of clock signals is achieved without one or more of the limitations of serially buffering of a reference clock, dependency between the difference clock generators and the noise associated therewith, common power supplies, inability to gate on and off a clock generator, and increased power consumption.

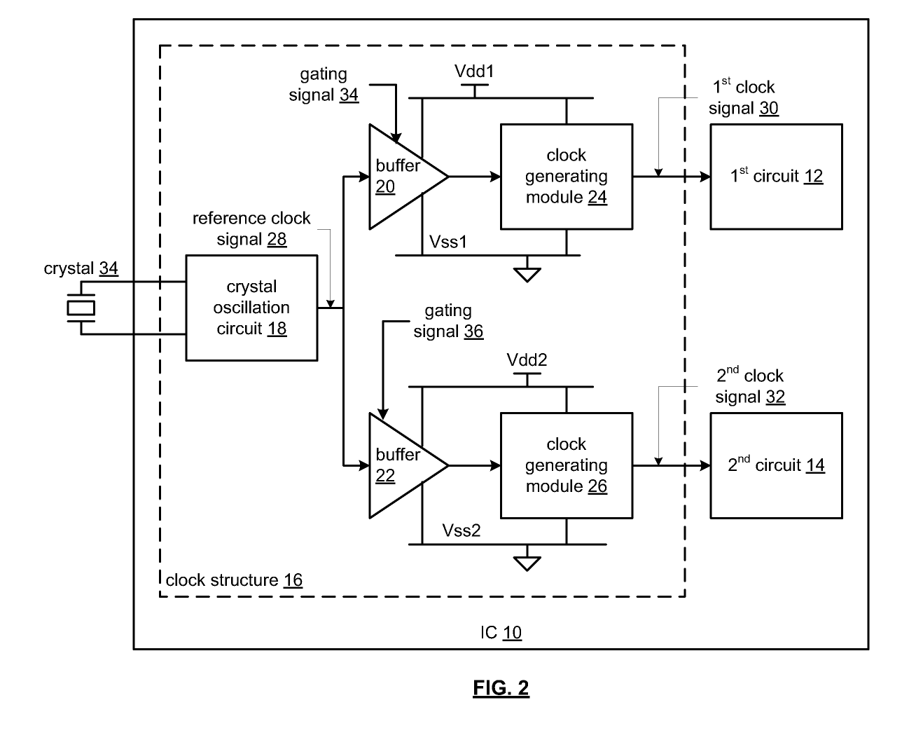

FIG. 2 is a schematic block diagram of another embodiment of an integrated circuit 10 that includes the first circuit 12, the second circuit 14, and the clock structure 16. The clock structure 16 is coupled to the off-chip crystal 34 and includes the crystal oscillation circuit 18, a plurality of gated buffers 20-22, and the plurality of clock generating modules 24-26. In this embodiment, when the first gated buffer 20 is gated on, the first clock generating module 24 is enabled and when the second gated buffer 22 is gated on, the second clock generating module 26 is enabled.

In addition, buffer 20 and the first clock generating module 24 are powered from first power supply lines (e.g., Vdd1 and Vss1) and buffer 22 and the second clock generating module 26 are powered from second power supply lines (e.g., Vdd2 and Vss2). As such, noise that is coupled from one circuit to another via power supply lines is substantially eliminated.

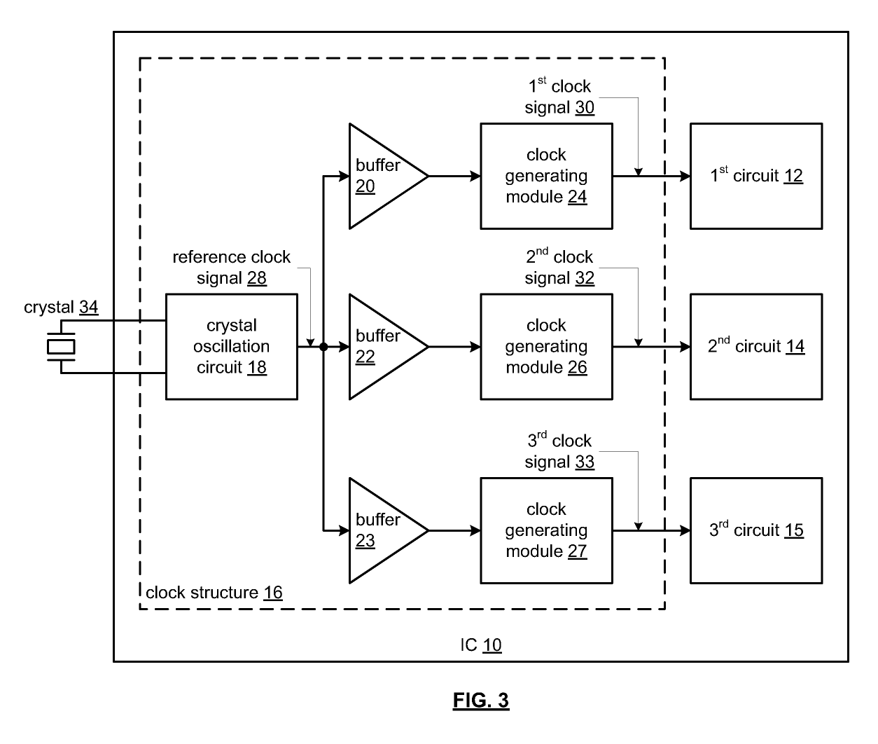

FIG. 3 is a schematic block diagram of another embodiment of an integrated circuit 10 that includes the first circuit 12, the second circuit 14, a third circuit 15, and a clock structure 16. The clock structure 16 is coupled to an off-chip crystal 34 and includes a crystal oscillation circuit 18, a plurality of buffers 20, 22, and 23, and a plurality of clock generating modules 24, 26, and 27. The crystal oscillation circuit 18 converts a vibration of the crystal 34 into a reference clock signal 28. For example, the crystal 34 may produce a vibration at 26 MHz, which is converted into a 26 MHz clock signal.

Buffers 20, 22, and 23 individually buffer the reference clock signal 18 and provide the buffered reference clock signal 18 to their corresponding clock generating module 24, 26, and 27. For example, buffer 20 buffers the reference clock signal 18 and provides the buffered clock signal to clock generating module 24; buffer 22 buffers the reference clock signal 18 and provides the buffered clock signal to clock generating module 26; and buffer 23 buffers the reference clock signal 18 and provides the buffered clock signal to clock generating module 27.

The first clock generating module 24, when enabled, generates a first clock signal 30 based on the buffered reference clock signal 28 received from buffer 20. Similarly, the second and third clock generating modules 26 and 27, when enabled, generate, respectively, a second clock signal 32 based on the buffered reference clock signal 28 received from buffer 22 and a third clock signal 33 based on the buffered reference clock signal 28 received from buffer 23. The first, second, and/or third clock generating module 24, 26, and/or 27 may include one or more of a phase locked loop (PLL), a fractional-N synthesizer, a counter logic circuit, a frequency multiplier, and a frequency divider to generate one or more fixed or adjustable clock signals.

Each of the first, second, and third circuits 12, 14, and 15 may be a microprocessor, micro-controller, digital signal processor, microcomputer, central processing unit, field programmable gate array, programmable logic device, state machine, logic circuitry, analog circuitry, digital circuitry, and/or any device that manipulates signals (analog and/or digital) based on hard coding of the circuitry and/or operational instructions. In this embodiment, the first circuit 12 and second circuit 14 respectively receive one or more of the first or second clock signals 30 or 32 from the first or second clock generating module 24 or 26 to perform a first or second function at a rate corresponding to a first or second clock signal 30 or 32. Similarly, the third circuit 15 receives the one or more third clock signals 33 from the third clock generating module 27 to perform a third function at a rate corresponding to a third clock signal 33.

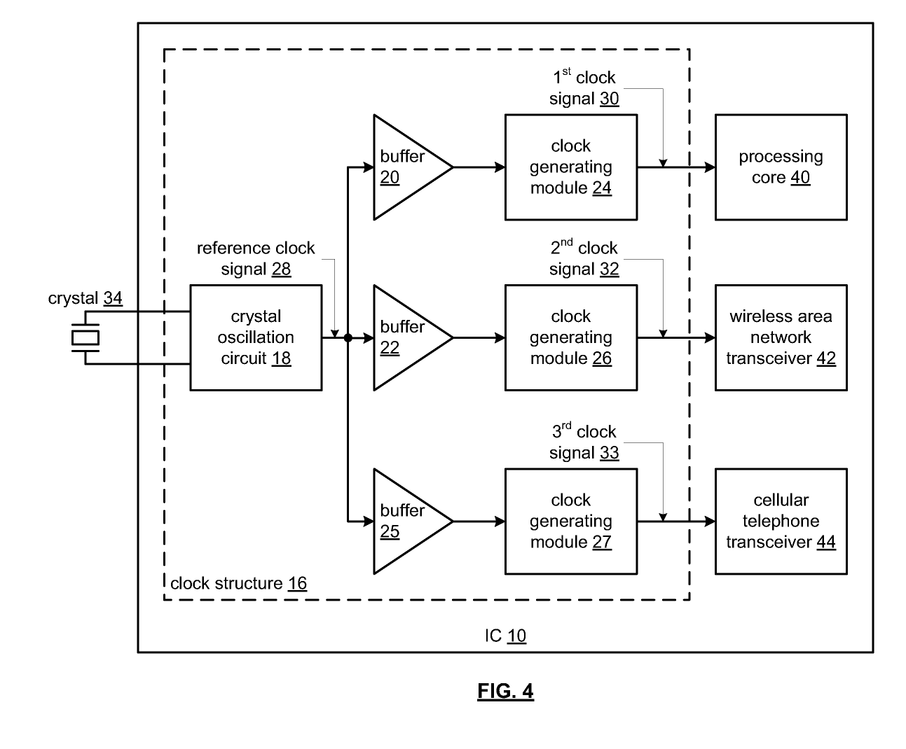

FIG. 4 is a schematic block diagram of another embodiment of an integrated circuit 10 that includes a processing core 40, a wireless area network (e.g., wireless local area network or wireless personal area network such as Bluetooth) transceiver 42, a cellular telephone transceiver (e.g., WCDMA, CDMA, GSM, EDGE, GPRS, etc), and a clock structure 16. The clock structure 16 is coupled to an off-chip crystal 34 and includes a crystal oscillation circuit 18, a plurality of buffers 20, 22, and 23, and a plurality of clock generating modules 24, 26, and 27. The clock structure 16 generates first, second, and third clock signals 30, 32, and 33, which are provided to the processing core 40, the wireless area network transceiver 42, and the cellular telephone transceiver 44.

The wireless area network transceiver 42 may include a receiver section for converting an inbound RF signal into an inbound symbol stream, a transmitter section for converting an outbound symbol stream into an outbound RF signal, and may further include a baseband processing module for converting outbound data into the outbound symbol stream and to convert the inbound symbol stream into inbound data in accordance with one or more wireless communication protocols (e.g., IEEE 802.11, Bluetooth, ZigBee, etc.). Similarly, the cellular telephone transceiver 42 may include a receiver section for converting an inbound cellular RF signal into an inbound cellular symbol stream, a transmitter section for converting an outbound cellular symbol stream into an outbound cellular RF signal, and may further include a baseband processing module for converting outbound cellular data into the outbound cellular symbol stream and to convert the inbound cellular symbol stream into inbound cellular data in accordance with one or more cellular communication protocols (e.g., WCDMA, GSM, EDGE, GPRS, CDMA, etc.).

As such, the baseband processing modules of the wireless area network transceiver and of the cellular telephone transceiver perform the physical layer of a communication protocol stack and may further perform the audio and/or video codec function for the IC. Note that the inbound data may include an inbound digital video signal, an inbound digital image signal, an inbound digital text signal, an inbound digital graphics signal, and the inbound digital audio signal and the outbound data may include an outbound digital audio signal, an outbound digital video signal, an outbound digital image signal, an outbound digital text signal, and/or an outbound digital graphics signal.

The processing core 40, which may include a first processing module and a second processing module, performs the remaining layers of the communication protocol stack (e.g., a data link layer, a network layer, a transport layer, a session layer, a presentation layer, and an application layer) and may further perform the operating system and user applications for the device incorporating the IC 10. As a specific example, the first processing module may perform the remaining layers of the communication protocol stack while the second processing module performs the operating system and user applications.

As another example, the processing core 40 performs one or more user applications that process (e.g., generate, modify, utilize, convert, store, update, etc.) the inbound signal and/or the outbound signal. Such a user application may be a digital image capture algorithm, a digital image display algorithm, a video capture algorithm, a video display algorithm, a voice compression algorithm, a voice decompression algorithm, an audio capture algorithm, an audio playback algorithm, a web browser algorithm, an email algorithm, a text message algorithm, and/or a cellular telephony algorithm.

As yet another example, the processing core 40 performs an operating system algorithm to manage the hardware and software resources of a wireless communication device that includes the IC 10. In general, the operating system controls allocation of memory, manage processes (e.g., coordinates operation of the one or more user applications), prioritizing system requests, controls input and output devices, facilitates networking and managing file systems, and security functions. In addition, the operating system includes a user interface application (e.g., a graphical user interface) for ease of operation.

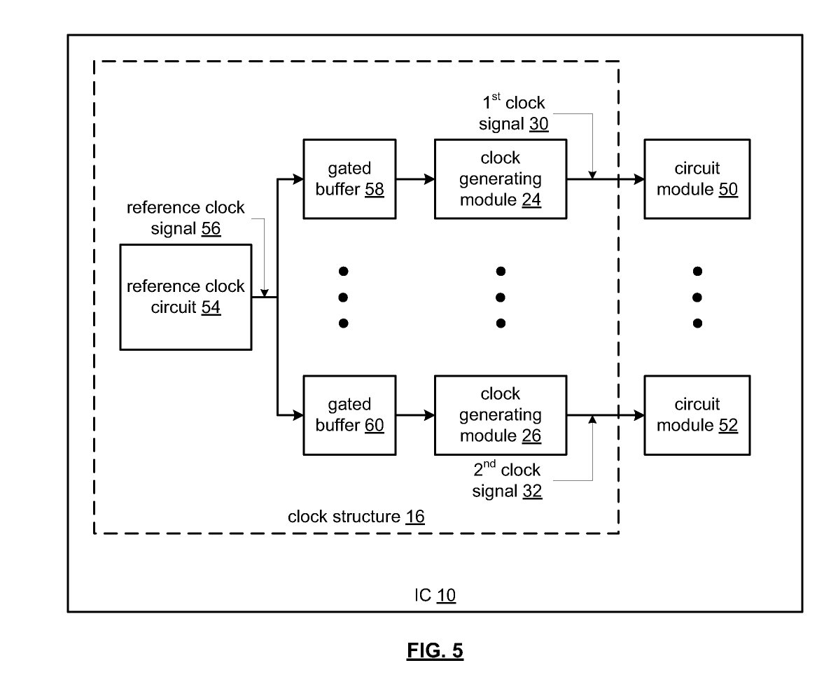

FIG. 5 is a schematic block diagram of another embodiment of an integrated circuit 10 that includes a plurality of circuit modules 50-52, and the clock structure 16. The clock structure 16 includes a reference clock circuit 54, a plurality of gated buffers 58-60, and a plurality of clock generating modules 24-26. The reference clock circuit 54, which may be a crystal oscillator circuit as shown in FIG. 1, a ring oscillator circuit, and/or a resistor-capacitor time constant circuit, generates a reference clock signal 56.

Gated buffers 58-60 individually buffer the reference clock signal 56 and, when gated on, provide the buffered reference clock signal 56 to their corresponding clock generating module 24-26. For example, gated buffer 58, when gated on, buffers the reference clock signal 56 and provides the buffered clock signal to clock generating module 24 and gated buffer 60 buffers the reference clock signal 56 and, when gated on, provides the buffered clock signal to clock generating module 26.

The first clock generating module 24, when enabled (e.g., when gated buffer 58 is gated on), generates a first clock signal 30 based on the buffered reference clock signal 56. Similarly, the second clock generating module 26, when enabled (e.g., when gated buffer 60 is gated on), generates a second clock signal 32 based on the buffered reference clock signal 56. The first and/or second clock generating module 24 and/or 26 may include one or more of a phase locked loop (PLL), a fractional-N synthesizer, a counter logic circuit, a frequency multiplier, and a frequency divider to generate one or more fixed or adjustable clock signals.

Each of the plurality of circuit modules 50-52 may be a single processing device or a plurality of processing devices. Such a processing device may be a microprocessor, micro-controller, digital signal processor, microcomputer, central processing unit, field programmable gate array, programmable logic device, state machine, logic circuitry, analog circuitry, digital circuitry, and/or any device that manipulates signals (analog and/or digital) based on hard coding of the circuitry and/or operational instructions. The processing module may have an associated memory and/or memory element, which may be a single memory device, a plurality of memory devices, and/or embedded circuitry of the processing module. Such a memory device may be a read-only memory, random access memory, volatile memory, non-volatile memory, static memory, dynamic memory, flash memory, cache memory, and/or any device that stores digital information. Note that when the processing module implements one or more of its functions via a state machine, analog circuitry, digital circuitry, and/or logic circuitry, the memory and/or memory element storing the corresponding operational instructions may be embedded within, or external to, the circuitry comprising the state machine, analog circuitry, digital circuitry, and/or logic circuitry.

In an embodiment, each of the circuit modules 50-53 receives the one or more of their respective clock signals 30-32, when generated, to perform a function at a rate corresponding to the respective clock signal 30-32. With such an embodiment, a clock structure that utilizes a single clock reference to generate a plurality of clock signals is achieved without one or more of the limitations of serially buffering of a reference clock, dependency between the difference clock generators and the noise associated therewith, common power supplies, inability to gate on and off a clock generator, and increased power consumption.

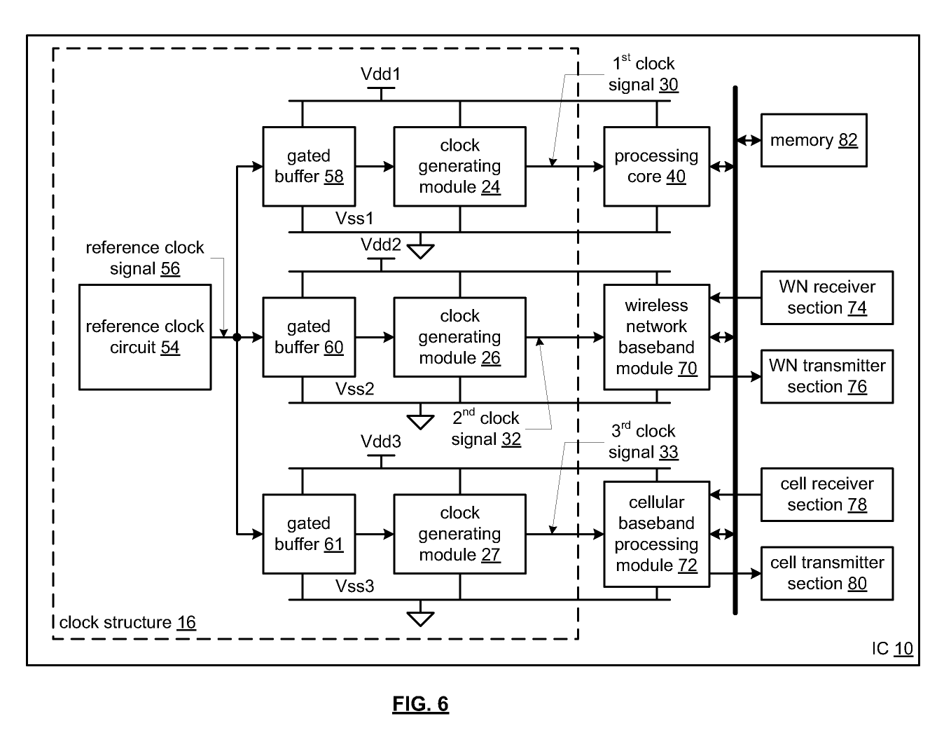

FIG. 6 is a schematic block diagram of another embodiment of an integrated circuit 10 that includes a processing core 40, a wireless area network (e.g., wireless local area network or wireless personal area network such as Bluetooth) baseband module 70, a wireless network (WN) transceiver section 76, a WN receiver section 74, a cellular telephone (e.g., WCDMA, CDMA, GSM, EDGE, GPRS, etc) baseband processing module 72, a cellular receiver section 78, a cellular transmitter section 80, memory 82, and a clock structure 16. The clock structure 16 includes a reference clock circuit 54, a plurality of gated buffers 58, 60, and 61, and a plurality of clock generating modules 24, 26, and 27. The reference clock circuit 54, which may be a crystal oscillator circuit as shown in FIG. 1, a ring oscillator circuit, and/or a resistor-capacitor time constant circuit, generates a reference clock signal 56.

Gated buffers 58, 60, and 61 individually buffer the reference clock signal 56 and, when gated on, provide the buffered reference clock signal 56 to their corresponding clock generating module 24, 26, and 27. The first clock generating module 24, when enabled, generates a first clock signal 30 based on the buffered reference clock signal 56 and the second clock generating module 26, when enabled, generates a second clock signal 32 based on the buffered reference clock signal 56. Similarly, the third clock generating module 27, when enabled (e.g., when gated buffer 61 is gated on), generates a third clock signal 33 based on the buffered reference clock signal 56.

The WN receiver section 74 converts an inbound RF signal into an inbound symbol stream and the WN transmitter section 76 converts an outbound symbol stream into an outbound RF signal. The WN baseband processing module 70 converts outbound data into the outbound symbol stream and converts the inbound symbol stream into inbound data in accordance with one or more wireless communication protocols (e.g., IEEE 802.11, Bluetooth, ZigBee, etc.). The cellular telephone receiver section 78 converts an inbound cellular RF signal into an inbound cellular symbol stream and the cellular transmitter section 80 converts an outbound cellular symbol stream into an outbound cellular RF signal. The cellular telephone baseband processing module 72 converts outbound cellular data into the outbound cellular symbol stream and converts the inbound cellular symbol stream into inbound cellular data in accordance with one or more cellular communication protocols (e.g., WCDMA, GSM, EDGE, GPRS, CDMA, etc.).

As such, the baseband processing modules 70 and 72 perform the physical layer of a communication protocol stack and may further perform the audio and/or video codec function for the IC. Note that the inbound data may include an inbound digital video signal, an inbound digital image signal, an inbound digital text signal, an inbound digital graphics signal, and the inbound digital audio signal and the outbound data may include an outbound digital audio signal, an outbound digital video signal, an outbound digital image signal, an outbound digital text signal, and/or an outbound digital graphics signal.

The processing core 40, which may include a first processing module and a second processing module, performs the remaining layers of the communication protocol stack (e.g., a data link layer, a network layer, a transport layer, a session layer, a presentation layer, and an application layer) and may further perform the operating system and user applications for the device incorporating the IC 10. As a specific example, the first processing module may perform the remaining layers of the communication protocol stack while the second processing module performs the operating system and user applications.

As another example, the processing core 40 performs one or more user applications that process (e.g., generate, modify, utilize, convert, store, update, etc.) the inbound signal and/or the outbound signal. Such a user application may be a digital image capture algorithm, a digital image display algorithm, a video capture algorithm, a video display algorithm, a voice compression algorithm, a voice decompression algorithm, an audio capture algorithm, an audio playback algorithm, a web browser algorithm, an email algorithm, a text message algorithm, and/or a cellular telephony algorithm.

As yet another example, the processing core 40 performs an operating system algorithm to manage the hardware and software resources of a wireless communication device that includes the IC 10. In general, the operating system controls allocation of memory, manage processes (e.g., coordinates operation of the one or more user applications), prioritizing system requests, controls input and output devices, facilitates networking and managing file systems, and security functions. In addition, the operating system includes a user interface application (e.g., a graphical user interface) for ease of operation.

As is further illustrated, gated buffer 58, clock generating module 24, and the processing core 40 are powered from first power supply lines (e.g., Vdd1 and Vss1); gated buffer 60, second clock generating module 26, and WN baseband processing module 70 are powered from second power supply lines (e.g., Vdd2 and Vss2); and gated buffer 61, third clock generating module 27, and cellular baseband processing module 72 are powered from third power supply lines (e.g., Vdd3 and Vss3). As such, noise that is coupled from one circuit to another via power supply lines is substantially eliminated.

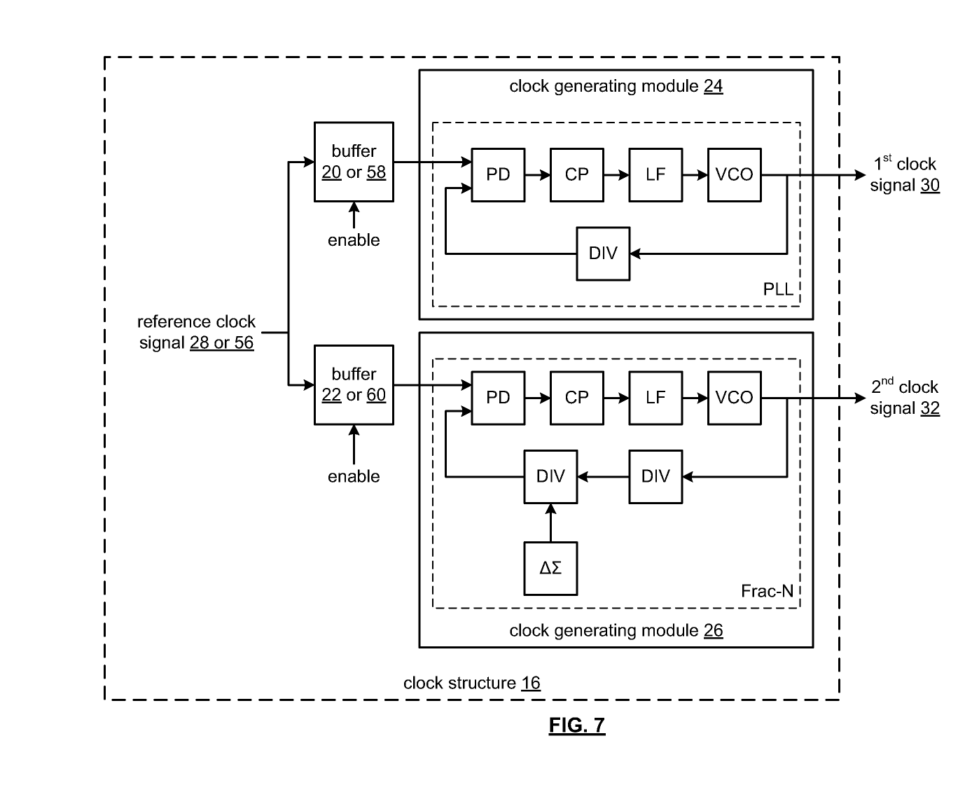

FIG. 7 is a schematic block diagram of an embodiment of the clock structure 16 that includes buffers 20-22 and/or 58-60, a first clock generating module 24, and a second clock generating module 26. The first clock generating module 24 includes a PLL that includes a phase detector (PD), a charge pump (CP), a loop filter (LF), a voltage controlled oscillator (VCO), and a feedback divider (DIV). The second clock generating module 26 includes a fractional N synthesizer that includes a phase detector (PD), a charge pump (CP), a loop filter (LF), a voltage controlled oscillator (VCO), a feedback divider (DIV). a second divider (DIV), and a delta sigma (ΔΣ) modulator.

In this embodiment, when the first buffer 20 or 58 is enabled, the PLL generates the first clock signal 30 from the reference clock signal 28 or 56. In general, the PD of the PLL compares the phase of the reference clock signal 28 or 56 with a feedback oscillation provided by the divider (DIV). If the phase of the feedback divider leads the phase of the reference oscillation, the PLL is running a little too fast. As such, the phase detector generates a down signal. If the phase of the feedback divider lags the phase of the reference oscillation, the PLL is running a little too slow. As such, the phase detector generates an up signal.

The charge pump converts the up or down signal into a current that slightly charges or discharges a capacitor of the loop filter. The voltage of the capacitor of the loop filter provides a control signal for the VCO, which generates the output clock signal, which, in this example, is the first clock signal 30. The feedback divider divides the frequency of the output oscillation to produce the feedback oscillation.

The fractional N synthesizer operates in a similar manner as the PLL, but the frequency of the feedback oscillation is varied between two values based on the delta sigma modulator. As such, a specific feedback divider value can be obtained.

The divider value of the PLL and of the fractional N synthesizer may be a fixed value or adjustable. In many radio transceiver applications, the first and second clocks are used to generate a local oscillation for a given frequency band. Typically, a frequency band will include multiple channels, which requires the generation of different local oscillations. Accordingly, the first and/or second clock generating modules 24 and/or 26 may be adjusted to provide the desired clock signal for a particular local oscillation.

As may be used herein, the terms “substantially” and “approximately” provides an industry-accepted tolerance for its corresponding term and/or relativity between items. Such an industry-accepted tolerance ranges from less than one percent to fifty percent and corresponds to, but is not limited to, component values, integrated circuit process variations, temperature variations, rise and fall times, and/or thermal noise. Such relativity between items ranges from a difference of a few percent to magnitude differences. As may also be used herein, the term(s) “coupled to” and/or “coupling” and/or includes direct coupling between items and/or indirect coupling between items via an intervening item (e.g., an item includes, but is not limited to, a component, an element, a circuit, and/or a module) where, for indirect coupling, the intervening item does not modify the information of a signal but may adjust its current level, voltage level, and/or power level. As may further be used herein, inferred coupling (i.e., where one element is coupled to another element by inference) includes direct and indirect coupling between two items in the same manner as “coupled to”. As may even further be used herein, the term “operable to” indicates that an item includes one or more of power connections, input(s), output(s), etc., to perform one or more its corresponding functions and may further include inferred coupling to one or more other items. As may still further be used herein, the term “associated with”, includes direct and/or indirect coupling of separate items and/or one item being embedded within another item. As may be used herein, the term “compares favorably”, indicates that a comparison between two or more items, signals, etc., provides a desired relationship. For example, when the desired relationship is that signal 1 has a greater magnitude than signal 2, a favorable comparison may be achieved when the magnitude of signal 1 is greater than that of signal 2 or when the magnitude of signal 2 is less than that of signal 1.

The present invention has also been described above with the aid of method steps illustrating the performance of specified functions and relationships thereof. The boundaries and sequence of these functional building blocks and method steps have been arbitrarily defined herein for convenience of description. Alternate boundaries and sequences can be defined so long as the specified functions and relationships are appropriately performed. Any such alternate boundaries or sequences are thus within the scope and spirit of the claimed invention.

The present invention has been described above with the aid of functional building blocks illustrating the performance of certain significant functions. The boundaries of these functional building blocks have been arbitrarily defined for convenience of description. Alternate boundaries could be defined as long as the certain significant functions are appropriately performed. Similarly, flow diagram blocks may also have been arbitrarily defined herein to illustrate certain significant functionality. To the extent used, the flow diagram block boundaries and sequence could have been defined otherwise and still perform the certain significant functionality. Such alternate definitions of both functional building blocks and flow diagram blocks and sequences are thus within the scope and spirit of the claimed invention. One of average skill in the art will also recognize that the functional building blocks, and other illustrative blocks, modules and components herein, can be implemented as illustrated or by discrete components, application specific integrated circuits, processors executing appropriate software and the like or any combination thereof.

What is claimed is:

1. An integrated circuit (IC) comprises:
a first circuit coupled to perform a first function at a rate corresponding to a first clock signal;
a second circuit coupled to perform a second function at a rate corresponding to a second clock signal; and
a clock structure consisting of:
a crystal oscillation circuit coupled to convert a vibration of a crystal into a reference clock signal;
a plurality of buffers, wherein an input of each of the plurality of buffers is coupled to receive the reference clock signal; and
a plurality of clock generating modules, wherein each of the plurality of clock generating modules is coupled to a corresponding one of the plurality of buffers, wherein, when a first clock generating module of the plurality of clock generating modules is enabled, the first clock generating module generates the first clock signal based on the reference clock signal received from a first corresponding one of the plurality of buffers, and wherein when a second clock generating module of the plurality of clock generating modules is enabled, the second clock generating module generates the second clock signal based on the reference clock signal received from a second corresponding one of the plurality of buffers.

2. The IC of claim 1, wherein the plurality of buffers comprises:
a plurality of gated buffers, wherein gating on the first corresponding one of the plurality of gated buffers enables the first clock generating circuit and gating on the second corresponding one of the plurality of gated buffers enables the second clock generating circuit.

3. The IC of claim 1 further comprises:
a plurality of separate power supply lines, wherein a first power supply line of the plurality of separate power supply lines powers the first corresponding one of the plurality of buffers and the first clock generating module and a second power supply line of the plurality of separate power supply lines powers the second corresponding one of the plurality of buffers and the second clock generating module.

4. The IC of claim 1 further comprises:
a third circuit coupled to perform a third function at a rate corresponding to a third clock signal, wherein, when a third clock generating module of the plurality of clock generating modules is enabled, the third clock generating module generates the third clock signal based on the reference clock signal received from a third corresponding one of the plurality of buffers.

5. The IC of claim 4 further comprises:
the first circuit including a processing core;
the second circuit including at least one of a wireless local area network (WLAN) transceiver and a wireless personal area network (WPAN) transceiver; and
the third circuit including a cellular telephone transceiver.

6. The IC of claim 1, wherein each of the plurality of clock generating modules comprises at least one of:
a phase locked loop (PLL);
a fractional-N synthesizer;
a counter logic circuit;
a frequency multiplier; and
a frequency divider.

7. An integrated circuit (IC) comprises:
a plurality of circuit modules, wherein each of the plurality of circuit modules performs a function at a rate corresponding to one of a plurality of clock signals; and
a clock structure for generating the plurality of clock signals, wherein the clock structure consisting of:
a reference clock circuit coupled to produce a reference clock signal;
a plurality of gated buffers, wherein an input of each of the plurality of buffers is coupled to receive the reference clock signal; and
a plurality of clock generating modules, wherein each of the plurality of clock generating modules is coupled to a corresponding one of the plurality of gated buffers, and wherein each of the plurality of clock generating modules generates a corresponding one of the plurality of clock signals based on the reference clock signal received from a corresponding one of the plurality of gated buffers when the corresponding one of the plurality of gated buffers is gated on.

8. The IC of claim 7 further comprises:
a plurality of separate power supply lines, wherein a corresponding one of the plurality of separate power supply lines powers a corresponding one of the plurality of gated buffers and a corresponding one of the plurality of clock generating modules.

9. The IC of claim 7 further comprises:
a first one of the plurality of circuits including a processing core;
a second one of the plurality of circuits including at least one of a wireless local area network (WLAN) transceiver and a wireless personal area network (WPAN) transceiver; and
a third one of the plurality of circuits including a cellular telephone transceiver.

10. The IC of claim 7, wherein each of the plurality of clock generating modules comprises at least one of:
a phase locked loop (PLL);
a fractional-N synthesizer;
a counter logic circuit;
a frequency multiplier; and
a frequency divider.

11. The IC of claim 7, wherein the reference clock circuit comprises at least one of:
a crystal oscillator circuit;
a ring oscillator circuit; and
a resistor-capacitor time constant circuit.

12. A radio frequency integrated circuit (RFIC) comprises:
a wireless network transceiver coupled to transceive network data, wherein the wireless network transceiver operates at a rate corresponding to a wireless network clock signal;
a cellular transceiver coupled to transceive cellular data, wherein the cellular transceiver operates at a rate corresponding to a cellular clock signal;
a processing core coupled to perform at least one function, wherein the processing core operates at a rate corresponding to a processing core clock signal; and
a clock structure consisting of:
a reference clock circuit coupled to produce a reference clock signal;
a plurality of buffers, wherein an input of each of the plurality of buffers is coupled to receive the reference clock signal; and
a plurality of clock generating modules, wherein each of the plurality of clock generating modules is coupled to a corresponding one of the plurality of buffers, wherein, when a first clock generating module of the plurality of clock generating modules is enabled, the first clock generating module generates the wireless network clock signal based on the reference clock signal received from a first corresponding one of the plurality of buffers, wherein, when a second clock generating module of the plurality of clock generating modules is enabled, the second clock generating module generates the cellular clock signal based on the reference clock signal received from a second corresponding one of the plurality of buffers, and, when a third clock generating module of the plurality of clock generating modules is enabled, the third clock generating module generates the processing core clock signal based on the reference clock signal received from a third corresponding one of the plurality of buffers.

13. The RFIC of claim 12, wherein the wireless network transceiver comprises at least one of:
a wireless local area network (WLAN) transcevier; and
a wireless personal area network (WPAN) transceiver.

14. The RFIC of claim 12, wherein the plurality of buffers comprises:
a plurality of gated buffers, wherein gating on the first corresponding one of the plurality of gated buffers enables the first clock generating circuit, gating on the second corresponding one of the plurality of gated buffers enables the second clock generating circuit, and gating on the third corresponding one of the plurality of gated buffers enables the third clock generating circuit.

15. The RFIC of claim 12 further comprises:
a plurality of separate power supply lines, wherein a first power supply line of the plurality of separate power supply lines powers the first corresponding one of the plurality of buffers and the first clock generating module, a second power supply line of the plurality of separate power supply lines powers the second corresponding one of the plurality of buffers and the second clock generating module, and a third power supply line of the plurality of separate power supply lines powers the third corresponding one of the plurality of buffers and the third clock generating module.

16. The RFIC of claim 12, wherein each of the plurality of clock generating modules comprises at least one of:
a phase locked loop (PLL);
a fractional-N synthesizer;
a counter logic circuit;
a frequency multiplier; and
a frequency divider.

17. The RFIC of claim 12, wherein the reference clock circuit comprises at least one of:
a crystal oscillator circuit;
a ring oscillator circuit; and
a resistor-capacitor time constant circuit.
